(19) United States
(12) Patent Application Publication
(10) Pub. No.: US 2025/0391485 A1
(43) Pub. Date: Dec. 25, 2025

(54) MEMORY DEVICES FOR OUTPUTTING HARD DECISION DATA AND SOFT DECISION DATA, MEMORY CONTROLLERS FOR CONTROLLING MEMORY DEVICES, AND OPERATING METHODS OF MEMORY CONTROLLERS

(71) Applicant: Samsung Electronics Co., Ltd., Suwon-si (KR)

(72) Inventors: HYOJUNG JANG, Suwon-si (KR); JINYOUNG KIM, Suwon-si (KR); SEHWAN PARK, Suwon-si (KR); EUNHYANG PARK, Suwon-si (KR); JISANG LEE, Suwon-si (KR)

(21) Appl. No.: 19/171,791

(22) Filed: Apr. 7, 2025

(30) Foreign Application Priority Data
Jun. 19, 2024 (KR) 10 2024 0079794

(51) Int. Cl. G11C 16/34; G11C 16/26

(52) U.S. Cl. CPC G11C 16/349; G11C 16/26; G11C 16/3418

(57) ABSTRACT

An operating method of a memory controller configured to control a memory device, the operating method includes setting a read mode of the memory device to one of a normal read mode, a partial soft decision (SD) data read mode, and an all-SD data read mode, based on first reliability information and second reliability information representing a degree of degradation of the memory device, selectively receiving hard decision (HD) data, which is read from a first cell region of the memory device, in response to outputting a first read command for the first cell region of the memory device in the partial SD data read mode, and receiving HD data and SD data, which are read from a second cell region of the memory device, in response to outputting a second read command for the second cell region of the memory device in the partial SD data read mode.

### CROSS-REFERENCE TO RELATED APPLICATIONS

This application is based on and claims priority under 35 U.S.C. § 119 to Korean Patent Application No. 10-2024-0079794, filed on Jun. 19, 2024, in the Korean Intellectual Property Office, the disclosure of which is incorporated by reference herein in its entirety.

### BACKGROUND OF THE INVENTION

The inventive concept relates to memory devices for outputting hard decision data and soft decision data, memory controllers for controlling the memory devices, and operating methods of the memory controllers.

As non-volatile memory, flash memory may retain stored data even when power thereto is turned off. Memory systems, including flash memory, such as solid state drives (SSDs) and memory cards, have been widely used. Also, the memory systems are useful for storing or moving large amounts of data.

In order to improve error correction capability when reading data from memory cells of the flash memory, a method is provided for outputting hard decision data read based on a normal read level and soft decision data read based on one or more offset levels to a memory controller. However, the read latency required to output the soft decision data may degrade the read performance of the memory system.

### SUMMARY OF THE INVENTION

The inventive concept may provide memory devices capable of reducing read latency and improving read performance in relation to output of hard decision data and soft decision data, memory controllers for controlling the memory devices, and operating methods of the memory controllers.

According to an aspect of the inventive concept, there is provided an operating method of a memory controller configured to control a memory device, the operating method comprising: setting a read mode of the memory device to one of a normal read mode, a partial soft decision (SD) data read mode, and an all-SD data read mode, based on first reliability information and second reliability information representing a degree of degradation of the memory device; selectively receiving hard decision (HD) data, which is read from a first cell region of the memory device, in response to outputting a first read command for the first cell region of the memory device in the partial SD data read mode; and receiving HD data and SD data, which are read from a second cell region of the memory device, in response to outputting a second read command for the second cell region of the memory device in the partial SD data read mode.

According to another aspect of the inventive concept, there is provided a memory controller configured to control a memory device, the memory controller comprising: a processor that is configured to control a read operation for the memory device; and a read mode setting module that is configured to set a read mode of the memory device to a normal read mode when a degree of degradation of the memory device based on first reliability information is less than a first threshold and to set the read mode of the memory device to a partial soft decision (SD) data read mode when the degree of degradation of the memory device based on second reliability information is less than a second threshold, wherein the memory controller is configured to selectively receive hard decision (HD) data, which is read from a first cell region of the memory device, in response to outputting a first read command for the first cell region of the memory device in the partial SD data read mode, and wherein the memory controller is configured to receive HD data and SD data, which are read from a second cell region of the memory device, in response to outputting a second read command for the second cell region of the memory device in the partial SD data read mode.

According to another aspect of the inventive concept, there is provided a memory device communicating with a memory controller, the memory device comprising: a cell array that comprises a plurality of blocks, wherein each of the plurality of blocks comprises a plurality of word lines, and memory cells of each of the plurality of word lines are configured to store data of a plurality of pages; and a control logic that is configured to set a read mode for the cell array to one of a normal read mode, a partial soft decision (SD) data read mode, and an all-SD data read mode, based on mode setting information provided from the memory controller, wherein the memory device is configured to selectively output hard decision (HD) data, which is read from a first cell region of the cell array, in response to receiving a first read command for the first cell region of the cell array in the partial SD data read mode, and wherein the memory device is configured to output HD data and SD data which are read from a second cell region of the cell array, in response to receiving a second read command for the second cell region of the cell array in the partial SD data read mode.

### BRIEF DESCRIPTION OF THE DRAWINGS

Embodiments will be more clearly understood from the following detailed description taken in conjunction with the accompanying drawings in which:

FIG. 1 is a block diagram showing a memory system according to some embodiments;

FIGS. 2A, 2B, 2C, and 2D are diagrams showing examples of generating hard decision (HD) data and soft decision (SD) data;

FIGS. 3A, 3B, and 3C are diagrams showing examples of outputting the HD data and the SD data;

FIG. 4 is a block diagram showing an example of a memory controller according to some embodiments;

FIGS. 5 to 7 are flowcharts showing a method of operating the memory controller, according to some embodiments;

FIGS. 8A, 8B, and 8C are diagrams showing various examples of cell regions from which the SD data is output in a partial SD data read mode;

FIGS. 9A, 9B, 10A, and 10B are block diagrams showing examples of memory systems, according to some embodiments;

FIGS. 11 and 12 are diagrams showing examples of history read level (RL) information;

FIG. 13 is a flowchart showing an example of using flag information;

FIGS. 14A, 14B, and 14C are diagrams showing a case in which flag values are managed in conjunction with updates to history RL information;

FIG. 15 is a flowchart showing an example of managing flag values in conjunction with updates to history RL information;

FIGS. 16A and 16B are diagrams showing examples of read performance of a memory device according to some embodiments;

FIG. 17 is a flowchart showing a method of operating a memory controller, according to some embodiments;

FIG. 18 is a perspective view showing a block according to some embodiments; and

FIG. 19 is a block diagram showing an example in which a memory system according to some embodiments is applied to a solid state drive (SSD) system.

### DETAILED DESCRIPTION OF THE INVENTION

Hereinafter, embodiments are described in detail with reference to the accompanying drawings.

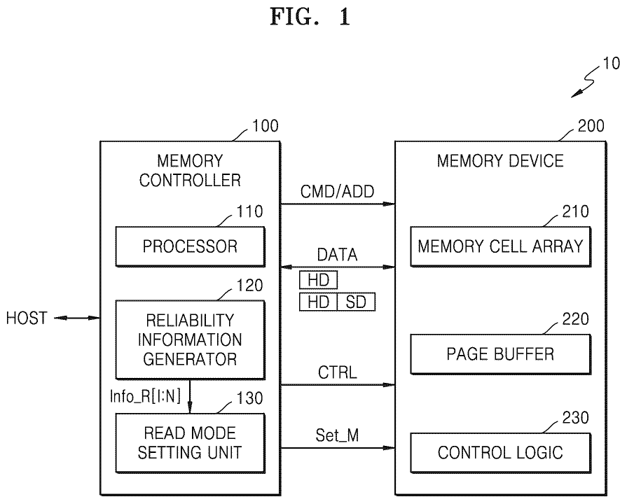

FIG. 1 is a block diagram showing a memory system 10 according to an embodiment.

Referring to FIG. 1, the memory system 10 may include a memory controller 100 and a memory device 200. The memory controller 100 may include a processor 110, a reliability information generator 120, and a read mode setting unit 130. Also, the memory device 200 may include a memory cell array 210, a page buffer 220, and a control logic 230. The memory controller 100 may provide a command CMD, an address ADD, and a control signal CTRL to the memory device 200, and the memory controller 100 may communicate data DATA with the memory device 200.

The memory system 10 may communicate with a host via various interfaces. For example, the memory system 10 may communicate with the host via various interfaces, such as a universal serial bus (USB), a multimedia card (MMC), an embedded MMC (eMMC), a peripheral component interconnection (PCI), PCI-express (PCI-E), advanced technology attachment (ATA), serial-ATA, parallel-ATA, a small computer small interface (SCSI), an enhanced small disk interface (ESDI), integrated drive electronics (IDE), Firewire, a universal flash storage (UFS), and nonvolatile memory express (NVMe).

The memory device 200 may include a non-volatile memory device, such as flash memory. In some embodiments, the memory system 10 may be embedded in an electronic device or provided as removable (e.g., attachable and detachable) memory. For example, the memory system 10 may be provided in various forms, such as an embedded UFS memory device, an eMMC, a solid state drive (SSD), a UFS memory card, a compact flash (CF) card, a secure digital (SD) card, a micro secure digital (Micro-SD) card, a mini secure digital (Mini-SD) card, an extreme digital (xD) card, and a memory stick. Also, the memory system 10 may be referred to as a storage device in terms of storing data in a non-volatile manner.

The memory controller 100 may control the memory device 200 to read data stored in the memory device 200 or write (or program) data in the memory device 200 in response to a write/read request from a host HOST. For example, the processor 110 may control (all) operations in the memory controller 100 and also control memory operations of the memory device 200. Specifically, the memory controller 100 may provide the address ADDR, the command CMD, and the control signal CTRL to the memory device 200 under control of the processor 110 and may control write, read, and erase operations of the memory device 200.

The memory cell array 210 may include a plurality of blocks, each of the blocks may include a plurality of word lines, and a plurality of memory cells may be (electrically) connected to each of the word lines. Also, a page may be defined as a unit that includes a plurality of memory cells or data corresponding to a program and read unit. When each of the memory cells stores a plurality of bits of data, one word line unit may include a plurality of pages. For example, when each of memory cells stores three bits of data, three pages of data may be written or read for each unit of the word lines. Hereinafter, embodiments in which the memory cells include flash memory cells are described in detail as an example. However, the embodiment is not limited thereto. In some embodiments, the memory cells may include resistive memory cells, such as resistive RAM (RcRAM) memory cells, phase change RAM (PRAM) memory cells, and/or magnetic RAM (MRAM) memory cells. As used herein, the term “and/or” includes any and all combinations of one or more of the associated listed items.

In an example operation, when reading data of a page, hard decision (HD) data and soft decision (SD) data may be read for each of the memory cells. The HD data may correspond to data determined based on a normal read level and the SD data may correspond to data determined based on an offset level that has a certain value offset from the normal read level. For example, the offset level may include a first offset level having a negative (−) offset and a second offset level having a positive (+) offset relative to the normal read level, and the SD data may be generated based on a combination of values determined according to the first and second offset levels. The memory controller 100 may receive HD data and SD data and perform an error correction code (ECC) decoding processing using the HD data and SD data. For example, the memory controller 100 may perform an error correction operation, such as low density parity check (LDPC). Herein, the term, level, may refer to a value (e.g., a magnitude) of an electrical parameter. For example, the level may refer to a value of a voltage or a value of a current. An offset level may refer to a different level from a reference level (e.g., normal level). For example, a positive offset level may mean that the absolute value of the corresponding electrical parameter is increased from a reference level. On the other hand, a negative offset level may mean that the absolute value of the corresponding electrical parameter is decreased from the reference level. The term, level, in some occasions, may refer to the severity of a degree. For example, when a degradation of a cell is described to have a high(er) level, it means that the degradation degree of the cell is severe (more severe) compared to other regular cells.

The HD data and SD data described above may be provided to the memory controller 100 according to various policies. For example, when an error occurs in normal data (e.g., HD data) read from the memory device 200, the memory device 200 may generate and output the SD data on the basis of control by the memory controller 100. Also, irrespective of the error detection result in the normal data, the memory device 200 may generate HD data and SD data on the basis of the control by the memory controller 100 and then output the HD data and SD data together.

In addition, with respect to a command for outputting the SD data, a read command (hereinafter, referred to as an SD read command) may be defined independently of a read command requesting provision of normal data (a HD read command). The memory device 200 may generate HD data in response to receiving a read command and output the HD data to the memory controller 100. On the other hand, when the SD read command is provided to the memory device 200, the memory device 200 may generate HD data and SD data together and then output the HD data and SD data to the memory controller 100.

A specific example operation according to an embodiment is described below.

The SD data may be generated in a variety of ways. For example, the SD data may be generated by performing an additional read operation using an offset level that is different from the normal read level (e.g., the read level for the HD data). Alternatively, data may be read using the normal read level, and the SD data may be generated by sensing the data at various sensing timings. When this method is used, the time required to generate the SD data may be reduced (compared to performing an additional read operation for the SD data), and the operation of generating the SD data based on the normal read level may be defined as a fast SD operation.

When the SD data is output to the memory controller 100, an SD decoding operation that uses both the HD data and the SD data may be performed. Accordingly, the error correction capability may be improved compared to an HD decoding operation that uses only the HD data. On the other hand, in the case of error correction using the SD data, SD data is additionally output to the memory controller 100, which may increase read latency and deteriorate the read performance. In addition, for example, in the case of the fast SD operation, the time required to generate the SD data may be reduced compared to a method of generating SD data using different read levels. However, the read latency may increase compared to the case of only reading the HD data, and the accuracy of SD data in the fast SD operation may deteriorate compared to a method of using different read levels (non-fast SD operation). Therefore, the error correction capability may deteriorate.

According to an embodiment, based on one or more pieces of reliability information representing the degree of degradation of the memory device 200, the memory controller 100 may set the read mode of the memory device 200 to either a normal read mode (e.g., a HD data read mode) or an SD data read mode. In addition, regarding the SD data read mode, the memory controller 100 may set the read mode of the memory device 200 to either a partial SD data read mode or an all-SD data read mode depending on the degree of degradation of the memory device 200.

For example, when the partial SD data read mode is set, only the HD data may be selectively read from some cell regions among all cell regions of the memory cell array 210, while both the HD data and SD data may be read together from other cell regions. On the other hand, when the all-SD data read mode is set, the HD data and SD data may be read together from all cell regions of the memory cell array 210.

In an embodiment, the read mode setting unit 130 may set the read mode of the memory device 200 on the basis of one or more pieces of reliability information provided from the reliability information generator 120. For example, the reliability information may include various pieces of information that may represent the degree of degradation of memory cells in the memory cell array 210, and the reliability information generator 120 may be defined as a unit that includes various components for generating the reliability information. For example, the reliability information generator 120 may generate first to Nth reliability information Info_R[1:N], and the read mode setting unit 130 may set the read mode of the memory device 200 using at least some of the first to Nth reliability information Info_R[1:N]. In embodiments, it is described that reliability or the degree of degradation determined based on the reliability information is compared to thresholds, but terms according to the inventive concept may be defined in various ways. For example, values extracted from various pieces of information that may represent the reliability or degree of degradation of the memory device 200 may be compared to one or more thresholds, and the read mode may be selected according to a preset procedure based on the comparison result.

In an embodiment, when a program/erase counting value for the memory device 200 is present in the first to Nth reliability information Info_R[1:N], the reliability information generator 120 may include a program/erase counter. In addition, when the number of errors or bit error rate (BER) that occurred in data read from the memory device 200 is present in the first to Nth reliability information Info_R[1:N], the reliability information generator 120 may include an error correcting code (ECC) circuit. In addition, regarding the read level used for the read operation, when an offset value corresponding to history read level (RL) information is present in the first to Nth reliability information Info_R[1:N], the reliability information generator 120 may include table information (or a circuit storing the table information) including the history read level information.

In the partial SD data read mode, the cell region from which the HD data and SD data are read together may correspond to a region set in advance or a region varying depending on the degree of degradation of the memory device 200. A cell region may correspond to various units. For example, the cell region may correspond to a page unit, a word line unit, a block unit, or a combination thereof.

Each of the memory cells may correspond a multi level cell (MLC), a triple level cell (TLC), a quad level cell (QLC), or a cell storing a large number of bits. In case of the TLC, the memory cell array 210 may include pages storing various types of data, such as least significant bit (LSB), central significant bit (CSB), and most significant bit (MSB), and the HD data and SD data may be read together only for some of the pages. In addition, when the cell region corresponds to a word line unit, the memory cell array 210 may include a plurality of word lines. The HD data and SD data may be read together only for some of the word lines. In addition, when the cell region corresponds to a block unit, the memory cell array 210 may include a plurality of blocks. The HD data and SD data may be read together only for some of the blocks.

Also, in embodiments, the cell region from which the HD data and SD data are read together may be set as a combination of various units. For example, in a case in which the HD data and SD data are read together for some word lines (e.g., at least one word line), each unit of the word lines may include the LSB page, CSB page, and MSB page described above, and the HD data and SD data may be read together only for some of the pages. Also, in a case in which the HD data and SD data are read together for some blocks (e.g., at least one block), the HD data and SD data may be read together only for some word lines (e.g., at least one word line) and/or some pages (e.g., at least one page) in each of the blocks.

In addition, the cell region from which the HD data and SD data are read may be preset, and information related thereto may be set in the memory device 200 or in the memory controller 100. In one example operation, the memory controller 100 may provide the memory device 200 with mode setting information Set_M related to the set (preset) read mode. When a region for which read is requested corresponds to the preset cell region, the memory device 200 may read HD data and SD data together and output the HD data and SD data to the memory controller 100.

According to the embodiment described above, the application range of the fast SD may be operated differentially depending on the degree of degradation of the memory device 200. Accordingly, the increase in read latency due to the application of fast SD may be minimized, and the reliability of data may be improved while minimizing the deterioration of performance of the memory device 200.

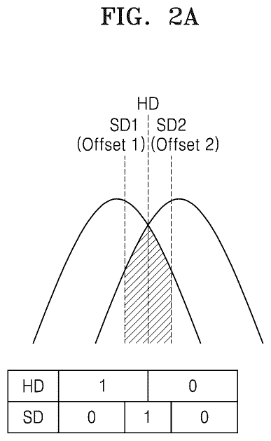

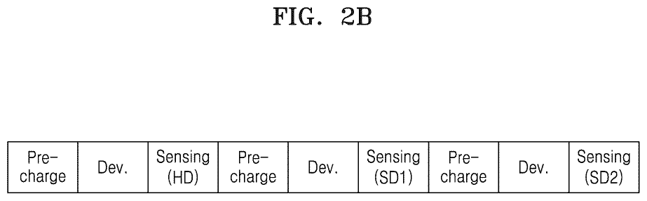

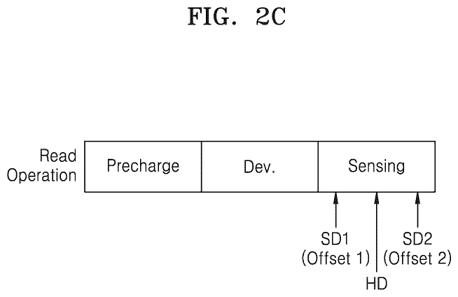

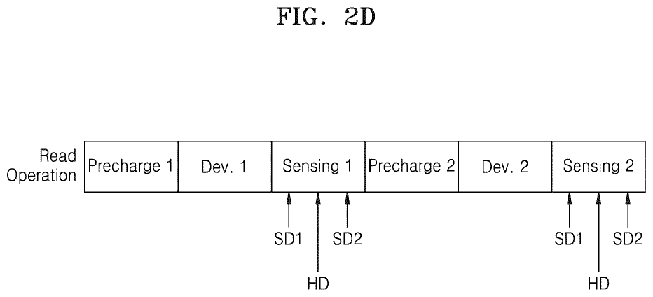

FIGS. 2A, 2B, 2C, and 2D are diagrams showing examples of generating HD data and SD data.

The HD data and SD data may be generated through various methods. The HD data and SD data may be distinguished from each other through different read levels. For example, word line voltages having different levels are applied to a word line through different read operations, and the HD data and SD data may be generated through separate read operations. Alternatively, according to the fast SD method, the HD data corresponding to the normal read level and the SD data corresponding to the offset level may be generated together by using different sensing timings in a sensing period of one read operation (including the normal read level for the HD data). For example, when the sensing timing is relatively fast, a data value may be determined based on a relatively low threshold voltage level. On the other hand, when the sensing timing is relatively late, the data value may be determined based on a relatively high threshold voltage level.

Referring to FIG. 1 and FIG. 2A, the memory device 200 may output, as the HD data, data determined based on the normal read level and output, as the SD data, data determined based on the offset level. The offset level may include a first offset level Offset 1 having a level less than the normal read level by a first offset and a second offset level Offset 2 having a level greater than the normal read level by a second offset.

For example, the HD data of a memory cell having a threshold voltage lower than the normal read level may have a value of “1” and the HD data of a memory cell having a threshold voltage higher than the normal read level may have a value of “0.” In addition, the SD data of a memory cell having a threshold voltage lower than the first offset level Offset 1 or higher than the second offset level Offset 2 may have a value of “0,” but the SD data of a memory cell having a threshold voltage between the first offset level Offset 1 and the second offset level Offset 2 may have a value of “1.” Alternatively, the SD data may be generated such that the SD data of a memory cell having a threshold voltage lower than the first offset level Offset 1 or higher than the second offset level Offset 2 has a value of “1,” and the SD data of a memory cell having a threshold voltage between the first offset level Offset 1 and the second offset level Offset 2 has a value of “0.” The SD data may include information indicating whether a memory cell has a strong error or a weak error, and various parameters, such as coefficients used in error correction operations, may be calculated based on the HD data and SD data.

Also, the read operation may include a plurality of periods, for example, a precharge period, a develop period, and a sensing period. In the precharge period, a sensing node may be precharged to a certain level of voltage. Also, the develop period may exhibit characteristics in which the voltage level of the sensing node changes depending on the data stored in the memory cell. For example, when the memory cell is programmed with a relatively low threshold voltage corresponding to an on-cell, the voltage level of the sensing node may drop rapidly. On the other hand, when the memory cell is programmed with a relatively high threshold voltage corresponding to an off-cell, the voltage level of the sensing node may drop gently.

FIG. 2B shows an example of generating SD data using a plurality of read levels. A plurality of read operations may be performed to generate HD data and SD data. For example, the HD data may be generated through a first read operation for applying a word line voltage having a normal read level. Also, the SD data may be generated based on first SD data SD1 determined through a second read operation for applying a word line voltage corresponding to a first offset level Offset 1 and second SD data SD2 determined through a third read operation for applying a word line voltage corresponding to a second offset level Offset 2.

FIG. 2C shows an example of a fast SD operation. As shown in FIG. 2C, the sensing operations may be performed at least two different sensing timings so as to determine HD data and SD data in the (same) sensing period. The values of data based on the first offset level Offset 1, the normal read level, and the second offset level Offset 2 in the embodiment may be determined according to the sensing timings described above, and the HD data and SD data may be generated through the sensing operations described above.

Also, referring to FIG. 2D, each of the memory cells may store more than 2 bits of data, and the memory cells may have three or more threshold voltage distributions depending on program states thereof. In this case, in order to determine the value of more than 2 bits of data in the memory cell, sensing operations of data may be required at least two threshold voltage distribution locations. Accordingly, each of the read operations may include a plurality of read periods. In an example of FIG. 2D, first and second read periods are illustrated. A first read period may include a first precharge period, a first develop period, and a first sensing period, and the second read period may include a second precharge period, a second develop period, and a second sensing period (after the first read period). A sensing operation similar to that in the embodiment of FIG. 2C may be performed in each of the first read period and the second read period. Accordingly, the HD data and SD data may be generated in each of the first read period and the second read period.

According to embodiments, in an SD data read mode, the SD data may be generated based on various methods described above with reference to FIGS. 2A, 2B, 2C, and 2D. In an embodiment, when SD data is generated according to the fast SD method, the SD data may be defined as being generated based on the method illustrated with reference to FIGS. 2C and 2D.

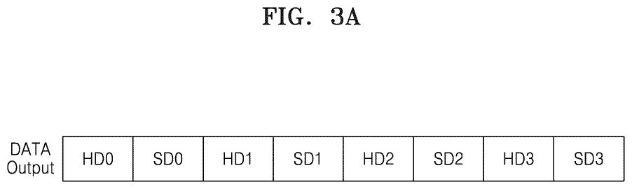

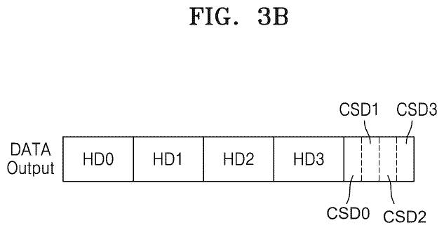

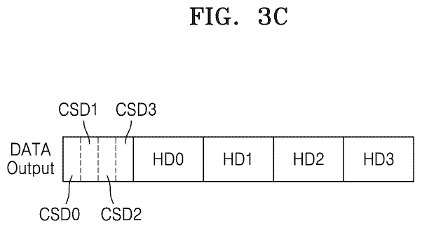

FIGS. 3A, 3B, and 3C are diagrams showing examples of outputting the HD data and the SD data. In FIGS. 3A, 3B, and 3C, a page is defined as a read unit, and each page includes four sectors. These diagrams illustrate cases in which first to fourth HD data HD0 to HD3 and first to fourth SD data SD00 to SD3 for four sectors are read from the page.

The HD data and SD data of pages read from a memory device (e.g., the memory device 200) may be output to a memory controller (e.g., the memory controller 100) in various ways. Referring to of FIG. 3A, the HD data and SD data may be read from a cell region of the memory device, and the HD data and SD data of each sector may be sequentially output to the memory controller. For example, after the first HD data HD0 and the first SD data SD0 are output, the second HD data HD1 and the second SD data SD1 may be output.

Also, referring to FIGS. 3B and 3C, the SD data may be compressed in the memory device and output to the memory controller, and thus, the read latency may be reduced. In an example operation, the memory controller may generate compressed first to fourth SD data CSD0 to CSD3 on the basis of various types of compression algorithms. Also, as shown in FIG. 3B, the memory device may output the first to fourth HD data HD0 to HD3 to the memory controller and then output the compressed first to fourth SD data CSD0 to CSD3 to the memory controller. Alternatively, as shown in FIG. 3C, the memory device may output the compressed first to fourth SD data CSD0 to CSD3 to the memory controller and then output the first to fourth HD data HD0 to HD3 to the memory controller. The memory device may output the HD data and SD data to the memory controller in various ways.

In the above-described embodiment, the SD data and the compressed SD data are described separately. However, embodiments described below do not need to be limited to specific data formats, and thus, the SD data may be output to the memory controller or the compressed SD data may be output to the memory controller.

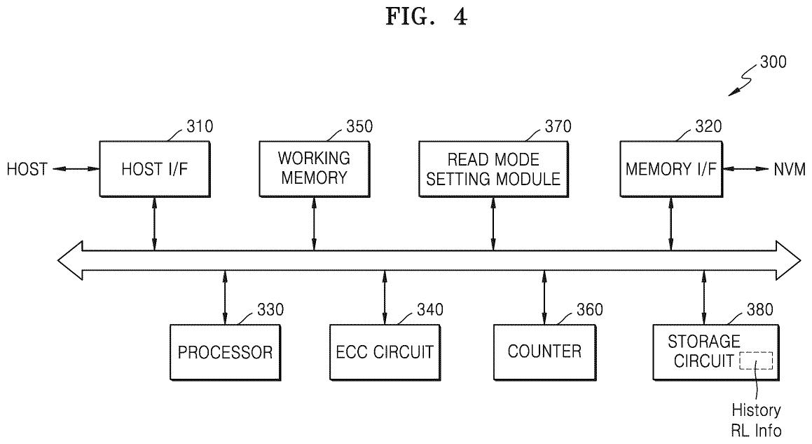

FIG. 4 is a block diagram showing an example of a memory controller 300 according to some embodiments.

Referring to FIG. 4, the memory controller 300 may include a host interface 310, a memory interface 320, a processor 330, an ECC circuit 340, a working memory 350, a counter 360, a read mode setting module 370, and a storage circuit 380. In some embodiments, the processor 330 may control (all) operations of the memory controller 300 by executing firmware loaded into the working memory 350. For example, the memory controller 300 may output commands/addresses (e.g., CMD/ADD) and control signals (e.g., CTRL) for controlling a memory operation of a memory device (e.g., a non-volatile memory device NVM) under the control of the processor 330.

The working memory 350 may be provided as various types of memory and may be provided, for example, as cache memory, such as dynamic random-access memory (DRAM), static random-access memory (SRAM), phase-change random-access memory (PRAM), and/or magnetic random-access memory (MRAM). In addition, as an example of firmware, a flash translation layer (FTL) may be loaded into the working memory 350. Also, various functions related to a flash memory operation may be performed by driving the FTL.

The host interface 310 may communicate with a host HOST through various types of interfaces according to the embodiments. Also, the memory interface 320 provides a physical (and/or an electrical) connection between the memory controller 300 and the memory device. For example, commands/addresses, data (e.g., DATA), and the like may be transmitted and received between the memory controller 300 and the memory device via the memory interface 320.

The ECC circuit 340 may perform ECC encoding processing on data requested to be recorded and perform ECC decoding processing on the read data. The ECC circuit 340 may generate an error detection result by performing the ECC decoding processing on a certain unit of data read from the memory device. For example, the ECC circuit 340 may provide at least one piece of information generated in relation to the ECC decoding processing to the read mode setting module 370 as the reliability information described above. For example, regarding the ECC decoding processing, information, such as the number of errors, the BER, the number of iterations of decoding processing, and the number of decoding failures occurring in previously performed read operations, may be provided to the read mode setting module 370 as the reliability information.

The counter 360 may provide a value, which is obtained by counting the number of program and/or erase operations on the memory device, to the read mode setting module 370 as the reliability information described above. The counting operations may be performed in various units. For example, the number of program operations may be counted in units of pages or blocks, and erase operations may be counted in units of blocks. In addition, according to embodiments, the reliability information may include at least one of the information obtained by counting the number of program operations and the information obtained by counting the number of erase operations.

The storage circuit 380 may include storage elements that store certain information in a volatile or non-volatile manner and may store at least one piece of information that represents the degree of degradation of the memory device. For example, as in the above-described embodiment, the memory controller 300 may manage table information including history RL information, and the storage circuit 380 may store the table information. The management of the history RL information may include operations of calculating and storing an optimal read level for a certain unit of the memory device 200 and updating the stored optimal read level. For example, an operation, such as valley search, may be performed to calculate an optimal read level on the basis of the control by the memory controller 300. In addition, the memory controller 300 may control a read operation for the memory device on the basis of the read level stored in the table information.

In an embodiment, the history RL information may correspond to an offset value relative to a certain base level. For example, as the degree of degradation of the memory device decreases, the optimal read level may have a value similar to the base level. On the other hand, as the degree of degradation of the memory device increases, the fluctuation range of the threshold voltage distribution of the memory cells may increase. In this case, the calculated optimal read level may have a relatively large difference from the base level, and the offset value may be calculated as a large value. In an embodiment, the offset value as the history RL information may be provided to the read mode setting module 370 as the reliability information described above.

The read mode setting module 370 may set the read mode for the memory device on the basis of various pieces of reliability information described above. For example, when it is determined on the basis of the reliability information that the degree of degradation of the memory device is small, the read mode setting module 370 may set the normal read mode as the read mode. Also, when it is determined that the degree of degradation of the memory device has increased, the read mode setting module 370 may set the partial SD data read mode as the read mode. Also, when it is determined that the degree of degradation of the memory device is very large, the read mode setting module 370 may set the all-SD data read mode as the read mode.

Also, the read mode setting module 370 illustrated in FIG. 4 may be provided as a hardware circuit or as software executed by the processor 330 or may be configured to have a combination of hardware and software. In addition, although not shown in FIG. 4, when a cell region in which the HD data and SD data are provided together are preset in the partial SD data read mode, the information related to the cell region may be further stored in the memory controller 300. Also, the diagram illustrates the working memory 350 and the storage circuit 380 as separate components. However, when the storage circuit 380 is provided as a volatile memory, at least some of the information stored in the storage circuit 380 may also be stored in the working memory 350.

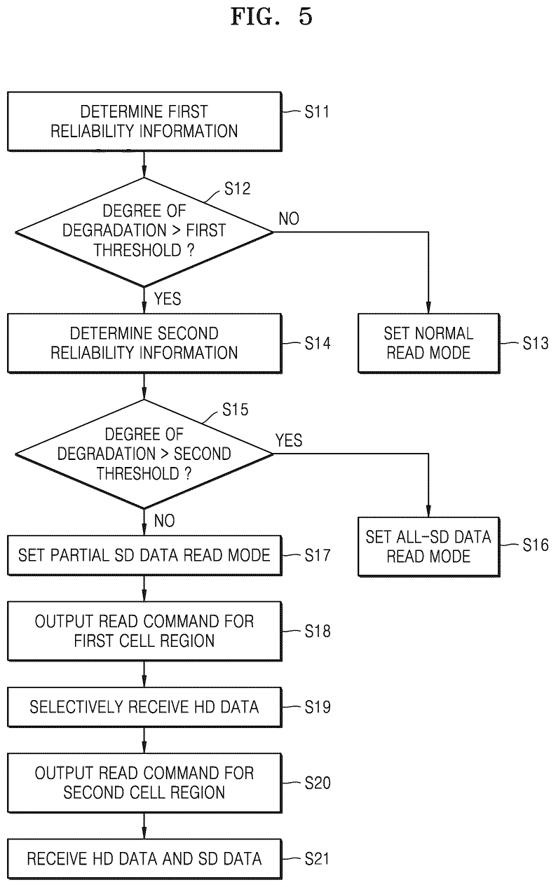

FIGS. 5 to 7 are flowcharts showing a method of operating the memory controller, according to some embodiments.

Referring to FIG. 5, a memory controller may determine first reliability information related to the degree of degradation of a memory device (S11), and it may be determined whether the degree of degradation determined based on the first reliability information exceeds a first threshold (S12). When the degree of degradation does not exceed the first threshold, a normal read mode may be set (S13).

On the other hand, when the degree of degradation exceeds the first threshold, the memory controller may determine second reliability information (S14), and it may be determined whether the degree of degradation determined based on the second reliability information is less than a second threshold (S15). When it is determined that the memory device is relatively significantly degraded because the degree of degradation exceeds the second threshold, the all-SD data read mode may be set (S16).

On the other hand, when the degree of degradation determined based on the second reliability information is less than the second threshold, it is determined that the memory device is not significantly degraded. Accordingly, the partial SD data read mode may be set (S17). In the partial SD data read mode, only HD data may be selectively generated and output from some cell regions among a plurality of cell regions of the memory device, but HD data and SD data may be generated and output together from the other cell regions of the memory device. For example, the memory controller may output a read command for a first cell region (S18). Also, since the first cell region corresponds to the cell region that selectively senses only HD data, the memory controller may selectively receive the HD data which is read from the first cell region (S19). In addition, the memory controller may output a read command for a second cell region (S20). Since the second cell region corresponds to the cell region that senses HD data and SD data, the memory controller may receive the HD data and SD data together which are read from the second cell region (S21).

Also, the setting of the read mode described above may be performed according to various policies. For example, a degree of degradation of the memory device may be determined at any timing or at a certain cycle, and the read mode may be selected based on the degree of degradation. In some embodiments, the selected read mode may be applied as a default mode, and subsequent read operations may be controlled based on the selected read mode. Alternatively, the degree of degradation of the memory device may be determined upon receiving a read request from a host, and a read mode may be selected (changed) based on the degree of degradation. The read operation according to the read request from the host may be controlled based on the selected read mode. Alternatively, the read mode setting according to embodiments may be performed based on various other methods. For example, when the read mode setting is performed based on the determination of the degree of degradation of the memory device as the program/erase cycle reaches a preset value, or when the optimal read level is newly calculated due to the occurrence of uncorrectable ECC (UECC) in the data, the determination of the degree of degradation of the memory device and the setting of the read mode may be performed as described above.

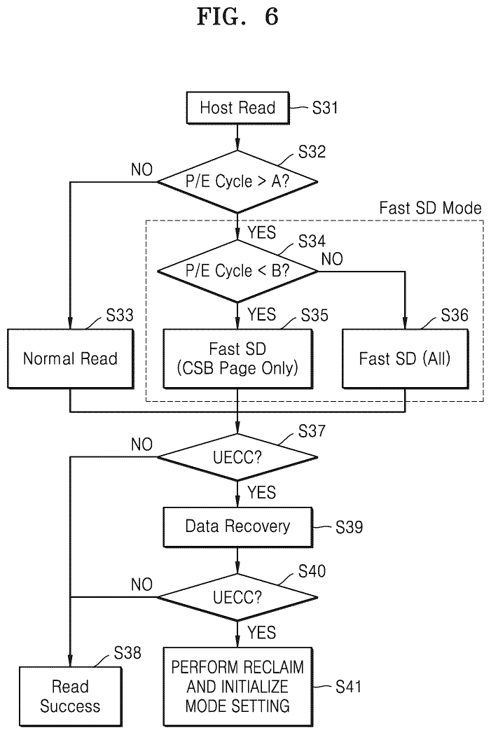

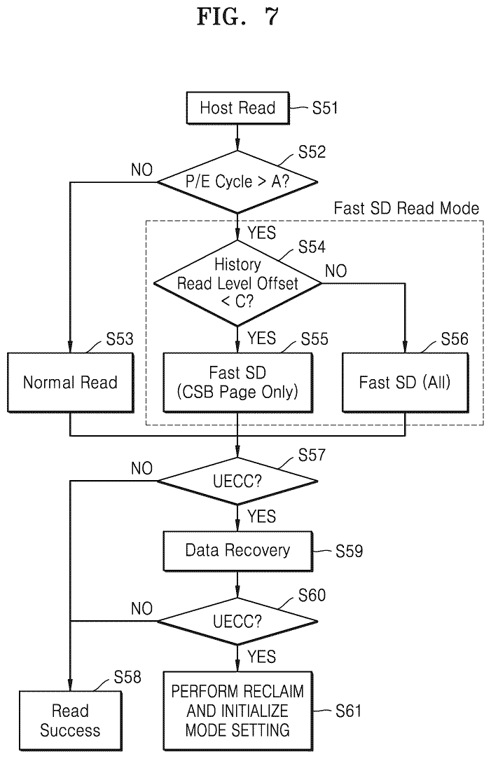

FIG. 6 and FIG. 7 illustrate specific example operations according to some embodiments. For example, FIG. 6 illustrates a case in which the first and second reliability information correspond to the same type of information, but FIG. 7 illustrates a case in which the first and second reliability information correspond to different types of information.

Referring to FIG. 6, the memory controller may receive a read request from a host (S31) and determine whether the number of program/erase cycles as the first reliability information is greater than a first threshold A (S32). When the number of program/erase cycles is less than the first threshold A, it is determined that the degree of degradation of the memory device is at a low level. Accordingly, the normal read mode may be set (S33).

On the other hand, when the number of program/erase cycles is greater than the first threshold A, it may be determined whether the number of program/erase cycles is less than a second threshold B (S34). When the number of program/erase cycles is less than the second threshold B, it is determined that the degree of degradation of the memory device is at an intermediate level. Accordingly, the partial SD data read mode may be set (S35). In addition, when the number of program/erase cycles is greater than the second threshold B, it is determined that the degree of degradation of the memory device is at a high level. Accordingly, the all-SD data read mode may be set (S36).

According to the read mode set as above, the read operation may be performed upon request from the host. Also, it may be determined whether there is a UECC in the read data (S37). When there is no UECC, it is determined that the read is performed successfully (S38). Also, the read data or error-corrected data may be provided to the host via the memory controller.

On the other hand, when there is a UECC in the read data, various recovery algorithms may be performed to recover the data. For example, recovery operations may be performed using read retry, valley search, or the like (S39). It may be re-determined whether there is a UECC in the data recovered by the above recovery algorithm (S40). When there is still a UECC, a reclaim operation may be performed to copy the data of at least one block containing data having an error to another block (S41).

When the data is copied, through the reclaim operation, to a normal block (e.g., a free block) that has not degraded, the reliability of the data may be increased. In an embodiment, when a reclaim is performed on one or more blocks of the memory device, a mode setting related to the read mode may be initialized. For example, when data stored in one or more blocks having a high degree of degradation is copied to another normal block, the read mode of the memory device may be initialized to the normal read mode, and the normal read mode may be set as the default mode for the memory device. Alternatively, regarding the reliability information about a block in which data has been newly copied, an initialization operation, such as resetting the number of program/erase cycles, may be performed.

Also, referring to FIG. 7, a memory controller may receive a read request from a host (S51) and determine whether the number of program/erase cycles as first reliability information is greater than a first threshold A (S52). When the number of program/erase cycles is less than the first threshold A, it is determined that the degree of degradation of the memory device is small. Accordingly, a normal read mode may be set (S53).

On the other hand, when the number of program/erase cycles is greater than the first threshold A, it may be determined whether the offset value of the history RL information as second reliability information is less than a third threshold C (S54). When the offset value is less than the third threshold C, the partial SD data read mode may be set (S55). Also, when the offset value is greater than the third threshold C, the all-SD data read mode may be set (S56).

In an embodiment, the memory controller may manage history RL information in various units for a plurality of blocks provided in one or more memory chips. Also, the offset value used as the second reliability information may be selected in various ways from among a plurality of pieces of information in the table information. For example, assuming that the history RL information is managed in units of blocks and that a plurality of offset values are stored for each block as the memory cells have a plurality of threshold voltage distributions, a plurality of offset values of a block to which a page requested to be read belongs are identified. Also, a preset or randomly selected offset value among the plurality of offset values or the largest offset value among the plurality of offset values may be used as the second reliability information.

According to the read mode set as above, a read operation may be performed according to a request from the host. Operations identical to or similar to those in the embodiment illustrated with reference to FIG. 6 may be performed, which include an operation of determining whether a UECC exists in the read data (S57), an operation of determining whether the read operation is successful (S58), an operation of performing recovery algorithms for recovering data (S59), an operation of re-determining whether a UECC exists in the recovered data (S60), and a reclaim operation for copying data to another block and an operation of initializing the read mode setting (S61).

Also, the embodiments described with reference to FIGS. 6 and 7 illustrate that the cell region from which the SD data is output is selected in units of pages, and the HD data and SD data are output together when data of a CSB page is read. However, according to the embodiments described above, the unit of the cell region from which the SD data is output may be set in various ways, such as in units of word lines and units of blocks.

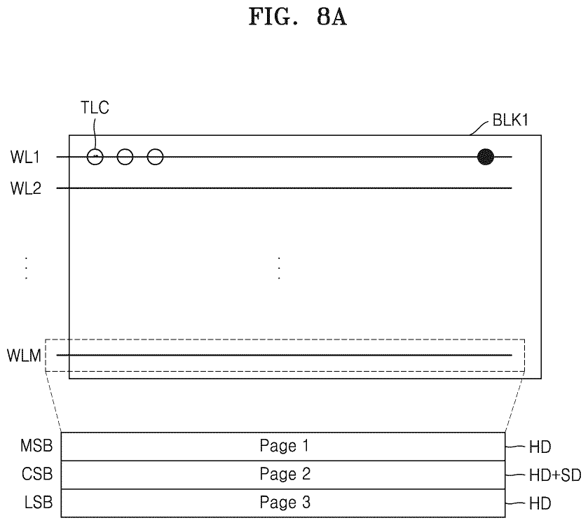

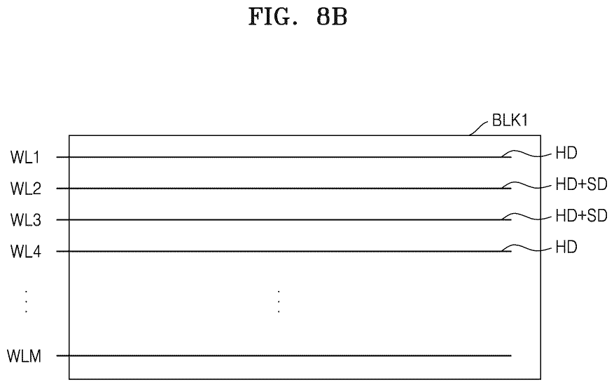

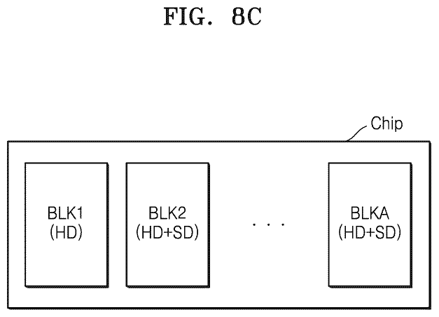

FIGS. 8A, 8B, and 8C are diagrams showing various examples of cell regions from which SD data is output in the partial SD data read mode according to some embodiments.

Referring to FIG. 8A, a memory device may include a plurality of blocks, one block (e.g., a first block BLK1) may include a plurality of word lines WL1 to WLM, and a plurality of memory cells may be (electrically) connected to each word line. For example, each memory cell may correspond to an MLC, a TLC, or a QLC, or may store more bits of data than any of these memory cells. In FIG. 8A, an example is shown in which each memory cell corresponds to the TLC. Herein, “M” may be a natural number greater than 2 or 4.

The number of memory cells (electrically) connected to each word line may correspond to the number of pieces of data constituting one or more pages. If the number of memory cells (electrically) connected to each word line is assumed to correspond to the number of pieces of data constituting one page, when each memory cell stores 3 bits of data, the memory cells (electrically) connected to each word line may store data corresponding to 3 pages (first to third pages). For example, the first page may correspond to the MSB page, the second page may correspond to the CSB page, and the third page may correspond to the LSB page.

Depending on the type of page, the conditions under which the characteristics of the page deteriorate may differ from each other. For example, some pages may be vulnerable to a situation in which the threshold voltage distribution level decreases due to the occurrence of charge loss caused by deterioration of retention characteristics. Also, other pages may be vulnerable to a phenomenon in which the threshold voltage distribution level increases due to the occurrence of soft programming caused by voltage applied during read operations.

In an embodiment, when a cell region to which a fast SD is applied is selected in units of page, the cell region may be selected by considering the operating environment of the memory device. For example, when some of the first to third pages are selected as pages to which the fast SD is applied, the pages may be selected based on various conditions, such as the temperature of the memory device and the frequency of read operations. According to an example operation, in the partial SD data read mode of FIG. 8A, the HD data and SD data are read and output together from the second page, but the HD data is selectively read and output from each of the first and third pages. Also, in an embodiment, at least one of the first page and the third page may be further selected as a cell region for outputting the SD data depending on the degree of degradation of the memory device. However, the embodiments are not limited thereto, and cell regions from which the SD data is output in units of page may be selected in various ways.

Referring to FIG. 8B, a first block BLK1 may include a plurality of word lines WL1 to WLM, and a cell region from which SD data is output may be selected in units of word line. Some of the word lines provided in the memory device may have relatively poor characteristics. For example, in flash memory having a vertical structure, the characteristics of word lines may differ from each other depending on the heights at which the word lines are located. Also, during a test process for memory devices, the word lines having relatively poor characteristics may be detected due to various causes, such as word line leakage. Based on the characteristics of the word lines, some word lines to which the fast SD is to be applied may be selected.

For example, FIG. 8B illustrates a case in which HD data is selectively read and output from some word lines (e.g., at least one word line), such as first and fourth word lines WL1 and WL4, but HD data and SD data are read and output together from second and third word lines WL2 and WL3. Also, the selection in units of page described with reference to FIG. 8A may be applied even in the embodiment described with reference to FIG. 8B. For example, when each of the second and third word lines WL2 and WL3 includes a plurality of pages, the HD data may be selectively read and output from some of the plurality of pages, but the HD data and SD data may be read and output together from the other pages.

Also, FIG. 8C illustrates a case in which a cell region is selected in units of block. For example, a memory device may include one or more chips, and each chip may include a plurality of blocks (e.g., first to A-th blocks BLK1 to BLKA). Herein, “A” may be a natural number greater than 2. Even in the case of the plurality of blocks in the memory device, blocks having relatively poor characteristics may be determined based on the physical locations of the blocks, the results from test processes, or the like. FIG. 8C illustrates a case in which HD data is selectively read and output from the first block BLK1, but HD data and SD data are read and output together from each of the second block BLK2 and the A-th block BLKA. In addition, the embodiments described with reference to FIGS. 8A and 8B may be applied to the embodiment in units of block described with reference to FIG. 8C. For example, the fast SD operation may be applied only to some word lines in the second block BLK2, and the fast SD operation may also be selectively applied to some pages among the plurality of pages in each word line.

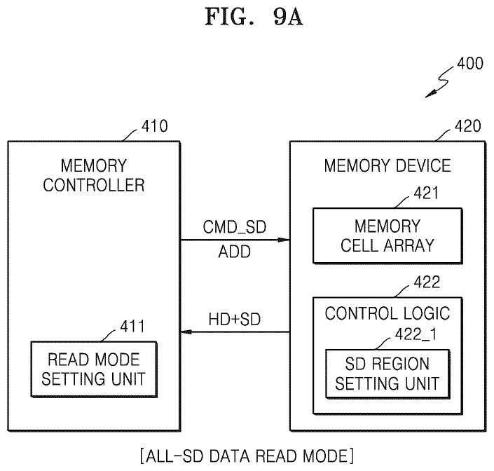

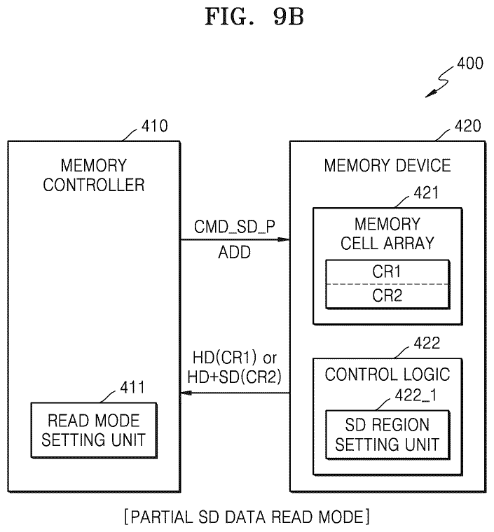

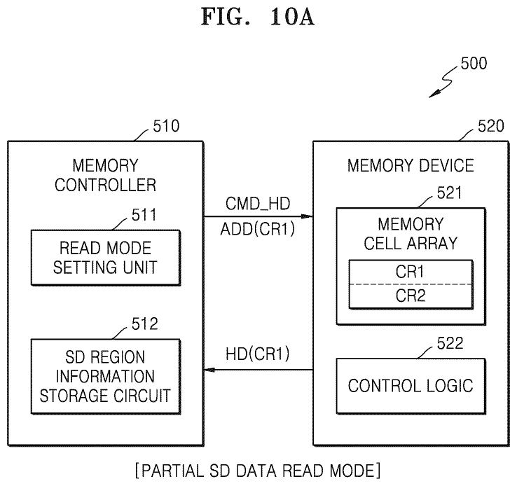

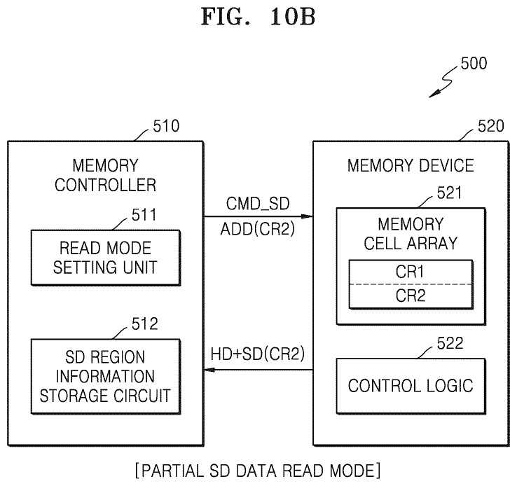

FIGS. 9A, 9B, 10A, and 10B are block diagrams showing examples of memory systems, according to some embodiments. FIGS. 9A and 9B illustrate a case in which the fast SD operation is performed in units of cell region on the basis of the control by the memory device, and FIGS. 10A and 10B illustrate a case in which the fast SD operation is performed in units of cell region on the basis of the control by the memory controller.

Referring to FIGS. 9A and 9B, a memory system 400 may include a memory controller 410 and a memory device 420, and the memory controller 410 may include a read mode setting unit 411 for setting a read mode for the memory device 420 on the basis of one or more pieces of reliability information. Also, the memory device 420 may include a memory cell array 421 and a control logic 422, and the control logic 422 may include an SD region setting unit 422_1.

In the partial SD data read mode according to the above-described embodiments, the information on cell regions from which the SD data is to be output may be preset and stored, and the memory device 420 may perform a setting operation to selectively read the SD data from some cell regions among the plurality of cell regions. The read mode setting unit 411 may include various components related to the setting operation. The example of FIGS. 9A and 9B shows that the SD region setting unit 422_1 is provided inside the control logic 422, but the SD region setting unit 422_1 may be located outside the control logic 422. The read mode setting unit 411 may perform various setting operations based on hardware and/or software so that, when a read request is made for a cell region to which the fast SD is to be applied, at least two sensing operations are performed during the sensing period of the read operation, compression is performed on the SD data, and the generated HD data and SD data are output to the memory controller 410. For example, control information for controlling all sequences performed in the read operation may be provided as hardware inside the control logic 422. Also, when the cell region to which the fast SD is applied is selected according to an address (e.g., a block address and a row address) provided from the memory controller, the control information is provided to circuits inside the memory device 420, and thus, at least two sensing operations, compression/output operations of SD data, or the like may be controlled. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

In an example operation, a command for selectively reading the SD data in units of cell region (hereinafter, referred to as a partial SD read command CMD_SD_P) between the memory controller 410 and the memory device 420 may be defined, and the partial SD read command CMD_SD_P may include different command information from SD read command CMD_SD for requesting reading of the SD data for all cell regions. When the all-SD data read mode is set as in FIG. 9A, the memory controller 410 may output the SD read command CMD_SD and the address ADD to the memory device 420, and the memory device 420 may read the HD data and SD data from the cell region indicated by the address ADD and output the HD data and SD data to the memory controller 410.

Also, when the partial SD data read mode is set as in FIG. 9B, the memory controller 410 may output the partial SD read command CMD_SD_P and the address ADD to the memory device 420, and the memory device 420 may selectively output only the HD data according to the cell region indicated by the address ADD or output the HD data and SD data together. For example, if a first cell region CRI of the memory cell array 421 is set to selectively output only HD data and a second cell region CR2 is set to output both HD data and SD data, when the address ADD indicates the first cell region CR1, only the HD data may be selectively read and output to the memory controller 410. On the other hand, when the address ADD indicates the second cell region CR2, the HD data and SD data may be read and output together to the memory controller 410.

Also, referring to FIGS. 10A and 10B, the memory system 500 may include a memory controller 510 and a memory device 520, and the memory controller 510 may include a read mode setting unit 511 and an SD region information storage circuit 512. In addition, the memory device 520 may include a memory cell array 521 and a control logic 522, and the memory cell array 521 may include a plurality of cell regions. For example, in the partial SD data read mode, it is assumed that only HD data is selectively output from the first cell region CR1, and both HD data and SD data are output together from the second cell region CR2.

The SD region information storage circuit 512 may store information of cell regions of the memory device 520, from which the HD data and SD data are output together in the partial SD data read mode. The information of cell regions may be generated in various ways and stored in the memory controller 510. For example, the information about a specific page (e.g., a CSB page), a specific word line, or a specific block may be provided from the memory device 520 to the memory controller 510 and stored in the memory controller 510. In addition, the information of other cell regions may be generated by the memory controller 510. For example, blocks to which the partial SD data read mode is to be applied may be determined based on a program/erase cycle counting operation of the memory controller 510, and information of the corresponding blocks may be stored in the SD region information storage circuit 512.

The memory controller 510 may selectively output a normal read command CMD_HD or an SD read command CMD_SD depending on the cell region in which reading is to be performed in the partial SD data read mode. For example, when performing a read operation on the first cell region CRI in the partial SD data read mode as illustrated in FIG. 10A, the memory controller 510 may output the normal read command CMD_HD and an address ADD (CR1) indicating the first cell region CRI to the memory device 520, and the memory device 520 may output the HD data read from the first cell region CRI to the memory controller 510. In addition, when performing a read operation on the second cell region CR2 in the partial SD data read mode as illustrated in FIG. 10B, the memory controller 510 may output the SD read command CMD_SD and an address ADD (CR2) indicating the second cell region CR2 to the memory device 520, and the memory device 520 may output the HD data and SD data read from the second cell region CR2 together to the memory controller 510.

Hereinafter, an embodiment is described in which flag information representing cell regions to which the fast SD is to be applied is managed in the partial SD data read mode. In addition, in relation to this embodiment, an embodiment is described in which table information including history RL information is used.

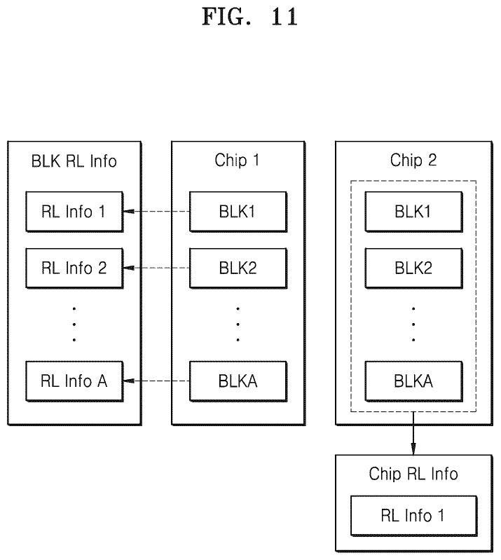

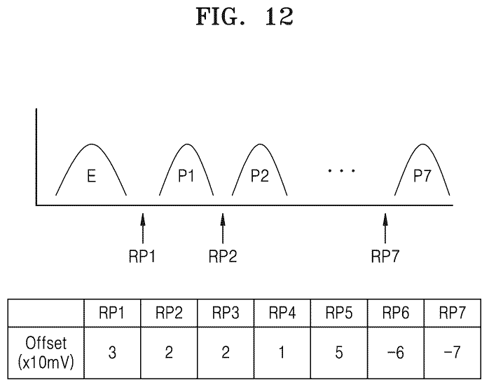

FIGS. 11 and 12 are diagrams showing an example of history RL information.

Referring to FIG. 11, a memory device may include one or more chips, and each chip may include a plurality of blocks. For example, FIG. 11 illustrates a case in which each of the first and second chips Chip1 and Chip2 includes first to A-th blocks BLK1 to BLKA.

When a failure occurs, such as when a UECC exists in the read data, the memory controller may calculate an optimal read level through a recovery operation, such as valley search, and store the calculated optimal read level. Subsequently, the read operation may be performed using the optimal read level stored in the table information, and thus, the possibility of successful data read may be increased. In addition, when a failure occurs in the read data, the optimal read level may be calculated again, and the newly calculated information may be updated. This technique may be referred to as a history RL management technique, and the history RL information may be stored and managed in various units (e.g., a page, a page group, a word line, a word line group, a block, a block group, a chip, a chip group, etc., and/or combinations thereof).

FIG. 11 illustrates a case in which history RL information is managed in units of block or units of chip. For example, the history RL information may include block RL information, such as first RL information corresponding to the first block BLK1 of the first chip Chip1 and second RL information corresponding to the second block BLK2 (of the first chip Chip1). In an example operation, the first block BLK1 may include a plurality of pages. When a read operation fails on any one page, the information related to a newly calculated optimal read level may be updated as the first RL information corresponding to the first block BLK1.

In an embodiment, the history RL information may be managed in units of chip. For example, the history RL information may include chip RL information, such as first RL information corresponding to the second chip Chip2. In an example operation, the read operation may be performed on a plurality of blocks in the second chip Chip2. When the read operation fails on at least one page in the second chip Chip2, the information related to the newly calculated optimal read level may be updated as the first RL information corresponding to the second chip Chip2.

FIG. 12 is a diagram showing a case in which offset values are managed as the history RL information.

Referring to FIG. 12, assuming that each memory cell of the memory device is a TLC storing 3 bits of data, the memory cells may be programmed to an erase state E and first to seventh program states P1 to P7. In addition, first to seventh read positions RP1 to RP7 may be defined as a plurality of read positions so as to determine threshold voltage distributions, and the optimal read level for determining data may be calculated at each of the first to seventh read positions RP1 to RP7.

The history RL information may be information containing various values. For example, a base level may be defined at each of the read positions, and offset values based on the base level may be calculated so as to calculate the optimal read level. When −1,000 mV corresponds to the base level at the first read position RP1, the optimal read level at the first read position RPI may correspond to −970 mV by reflecting the offset value. Also, when 3,000 mV corresponds to the base level at the seventh read position RP7, the optimal read level at the seventh read position RP7 may correspond to 2,930 mV by reflecting the offset value. In an embodiment, the base level of the read positions described above is stored in the memory controller, and the value of the base level does not change. However, the offset value may change with respect to the optimal read level on the basis of the update operation of the history RL information described above.

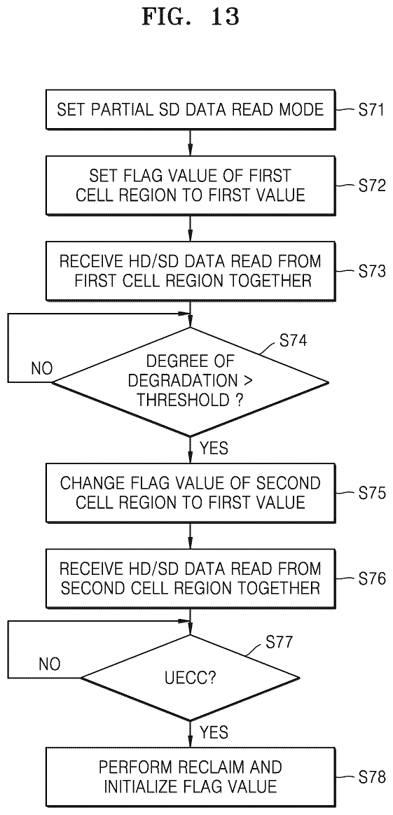

FIG. 13 is a flowchart showing an embodiment of managing a cell region to which fast SD is applied using flag information. FIG. 13 illustrates an example of varying the cell region to which the fast SD is applied on the basis of the operation of flag values in a partial SD data read mode.

According to the embodiments described above, a memory controller may set a read mode for a memory device to a partial SD data read mode (S71). For example, the degree of degradation of the memory device determined based on first and second reliability information may be compared to certain thresholds to set the read mode.

A first cell region may be preset as a cell region for outputting SD data in the partial SD data read mode, and a flag value corresponding to the first cell region may be set to a first value (S72). The memory controller may output a read command for the first cell region and receive HD data and SD data together, which are read from the first cell region, in response to the output of the read command (S73).

Subsequently, the memory controller may use at least one piece of reliability information at any point of time or at a certain cycle or upon a read request from the host so as to determine whether the degree of degradation of the memory device exceeds a certain threshold (S74). When the degree of degradation of the memory device exceeds the certain threshold, at least one cell region from which the SD data is to be output may be further selected. For example, the flag value corresponding to the second cell region may be changed from a second value to the first value (S75). The cell region corresponding to the flag value of the first value may correspond to the cell region that outputs the SD data, and the memory controller may receive the HD data and SD data together, which are read from the second cell region, in response to outputting the read command for the second cell region (S76).

The error detection/correction operation for data may be performed using the HD data and/or SD data which are read as described above, and it may be determined whether a UECC has occurred (S77). When a UECC occurs, one or more recovery algorithms may be performed to recover the error. When a UECC occurs even in the recovered data, a reclaim operation may be performed according to the embodiments described above, and the flag value may be initialized (S78).

The flag value may be stored and managed in various storage circuits inside the memory controller. For example, the flag value may be stored and managed together with history RL information in the storage circuit that stores the history RL information in the embodiment described above. In addition, the flag value may be managed so as to correspond to various units. For example, according to the embodiments described above, the flag value may have a value corresponding to units of page, a value corresponding to units of word line, or a value corresponding to units of block.

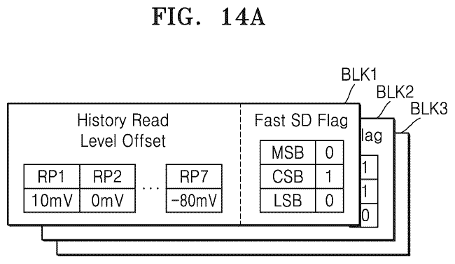

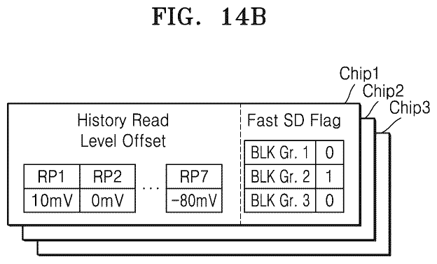

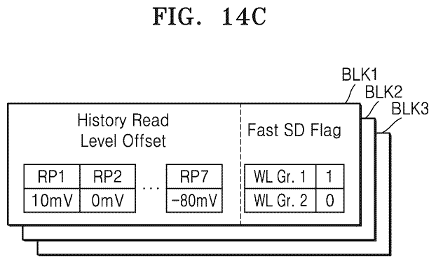

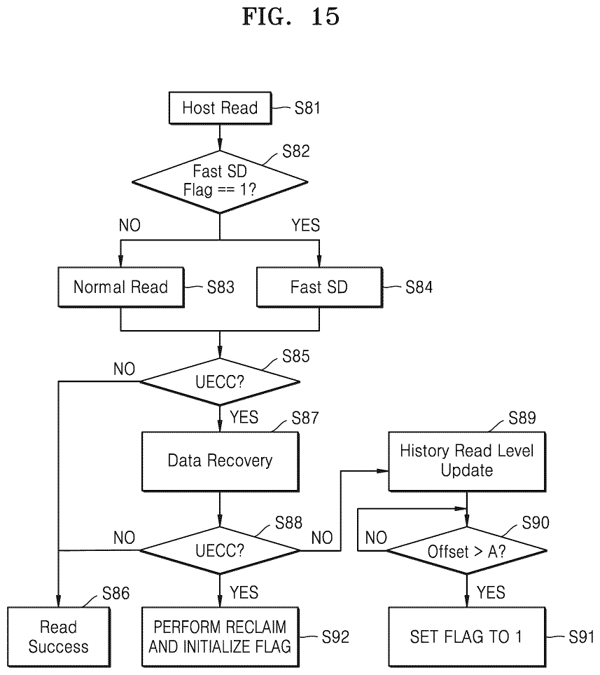

FIGS. 14A, 14B, and 14C are diagrams illustrating a case in which a flag value is managed in conjunction with an update of history RL information according to some embodiments. FIG. 15 is a flowchart showing an example of managing flag values in conjunction with updates of history RL information.

Based on one or more pieces of reliability information, the read mode of the memory device may be set to a normal read mode, a partial SD data read mode, or an all-SD data read mode. For example, in the partial SD data read mode, the memory controller may perform an operation of storing and managing the flag value so that the range of the cell regions from which the SD data are to be read is variable according to the degree of degradation of the memory device based on the offset value of the history RL information.

Referring to FIGS. 14A, 14B, and 14C, the history RL information may be managed in various units inside the memory controller. For example, FIG. 14 illustrates a case in which the history RL information is managed in units of block or units of chip. Also, a case is illustrated in which the flag value related to the application of fast SD according to the embodiments is stored together with the history RL information in the storage circuit that stores the history RL information. In addition, a case is illustrated in which the unit of the managed history RL information and the unit of the flag value are configured differently from each other. However, the embodiments are not limited thereto, and the history RL information may be managed in various units, such as block groups and chip groups. The unit of the managed flag value may be configured in the same manner as the management unit of the history RL information.

As illustrated in FIG. 14A, the history RL information for a first block BLK1 may include a plurality of offset values, and flag values set in cell regions of the first block BLK1 may be further stored in the storage circuit. For example, since the flag value is managed in units of page, when the flag value corresponding to the CSB page of the first block BLK1 is set to “1,” the HD data and SD data may be read together from the CSB page of the first block BLK1 and output to the memory controller. On the other hand, since the flag values corresponding to the MSB page and the LSB page are set to “0,” the HD data may be selectively read from the pages storing the MSB and LSB data of the first block BLK1 and output to the memory controller.

Also, regarding a second block BLK2, since the flag values corresponding to the MSB page and the CSB page of the second block BLK2 are set to “1,” the HD data and SD data may be read together from the MSB page and the CSB page and output to the memory controller. As described above, since different flag values are stored for blocks, the cell regions to which Fast SD is to be applied may be set differently for each block. In addition, since the flag value may change for each block as the degree of degradation of the memory device increases, the Fast SD application range optimized for the degree of degradation of each block may be set.

Also, referring to FIG. 14B, the history RL information is managed in units of chip, and the flag value set for each chip may be further stored in the storage circuit. For example, since the flag value is managed in units of block group, only the HD data is selectively output from blocks of some block groups. On the other hand, the HD data and SD data may be output together from blocks of other block groups. For example, the HD data and SD data may be read together from blocks of a second block group BLK Gr. 2. Although not shown in the example of FIG. 14B, the flag values in units of word line and/or in units of page may be additionally stored as flag values corresponding to each chip. For example, depending on the flag value, some word lines (e.g., at least one word line) from which the HD data and SD data are read together may be selected from among a plurality of word lines in a block of the second block group BLK Gr. 2. In addition, some pages from which the HD data and SD data are read together may be selected from among a plurality of pages. In addition, since the flag value is changed according to the degree of degradation of a first chip Chip1, the HD data and SD data may be read and output together from at least one block group among the first and third block groups BLK Gr. 1 and BLK Gr. 3.

Also, FIG. 14C illustrates the history RL information in units of block and the flag value in units of word line group. For example, since the read mode for the first block BLK1 is set to the partial SD data read mode, only HD data is selectively output from the word lines of a first word line group WL Gr. 1. On the other hand, the HD data and SD data may be output together from the word lines of a second word line group WL Gr. 2.

FIG. 15 shows an example operation when a partial SD data read mode is set. A memory controller may receive a read request from a host (S81), and a flag value corresponding to a cell region to which read is requested or a unit to which the cell region belongs (e.g., a page, a word line, a word line group, a block, a block group, a chip, a chip group, etc., and/or combinations thereof) may be identified. Also, it may be determined whether the flag value has a value of “1” representing an output of the SD data (S82). When data is read according to a normal read operation on the basis of the determination result (S83) (when the flag value is not “1”), the HD data is selectively output from the cell region to which read is requested. On the other hand, when data is read on the basis of the fast SD operation (S84) (when the flag value is “1”), the HD data and SD data may be read and output together from the cell region to which the read is requested.

It may be determined whether a UECC exists in the data that is read through the normal read or fast SD read (S85). When no UECC exists, it may be determined that the read is successful (S86). On the other hand, when a UECC exists, recovery operations, such as read retry and valley search, may be performed (S87). It is determined whether a UECC exists in the recovered data (S88). When no UECC exists, it may be determined that the read is successful (S86), and the history RL information may be updated according to the optimal read level newly calculated during a recovery process (S89).

As the history RL information, the offset value may correspond to the difference value compared to the base level according to the embodiment described above. A large offset value may indicate that the amount of shift in a threshold voltage distribution increases as the degree of degradation of the memory device increases. According to an embodiment, when the flag value corresponding to the unit to which the above-described cell region belongs is “0,” the offset value may be compared to a certain threshold A (S90). When it is determined that the offset value is greater than the certain threshold A, the flag value corresponding to the unit to which the above-described cell region belongs may be set to “1” (S91). That is, the normal read operation is performed for the cell region on the basis of the previous determination result. On the other hand, the subsequent read operation for the cell region may be performed on the basis of the fast SD operation according to the update of the flag value described above.

Also, when a UECC exists in the recovered data, reclaim may be performed on the block including the corresponding cell region, and the flag value may be initialized (S92).

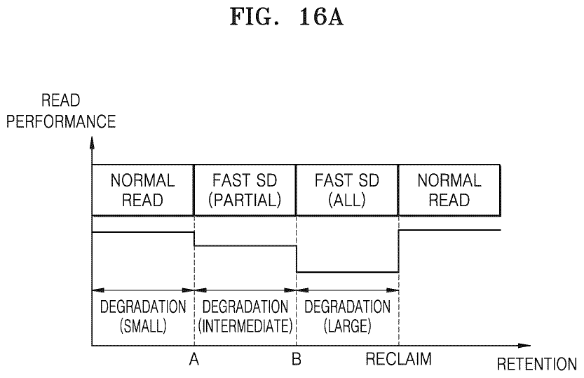

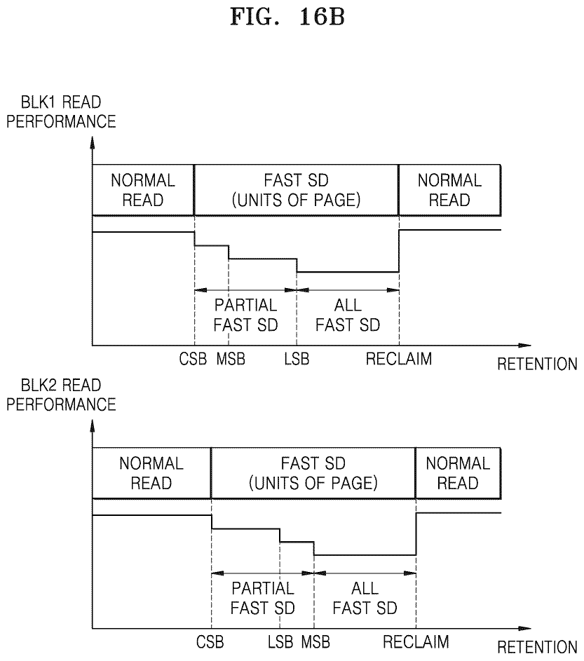

FIGS. 16A and 16B are diagrams showing examples of read performance of a memory device according to some embodiments.

FIG. 16A shows a case in which a cell region, to which fast SD is applied, is preset. The read mode is changed according to the data retention characteristics as the degree of degradation of a specific block, and the read performance may be changed on the basis of this change of the read mode. When the degree of degradation is less than a certain threshold A, the data is read based on the normal read mode. Accordingly, the read latency may be reduced and the read performance may be improved. Also, when the degree of degradation is greater than the threshold A and less than a certain threshold B, the data may be read based on the partial SD data read mode. Accordingly, the read performance may be lowered compared to the normal read mode. In addition, when the degree of degradation is greater than the threshold B, the data may be read based on the all-SD data read mode. Accordingly, the read performance may be lowered compared to the partial SD data read mode.

Also, FIG. 16B illustrates a case in which different read modes are applied to a first block BLK1 and a second block BLK2 which are different from each other, and illustrates a case in which a cell region, to which fast SD is applied in a partial SD data read mode, corresponds to units of page. The degrees of degradation of the first block BLK1 and the second block BLK2 may be different from each other. Accordingly, the timing of entering the partial SD data read mode or the all-SD data read mode may be different for each block. In addition, according to the above-described embodiment, the flag value representing cell regions from which the SD data is to be output may be updated based on the degree of degradation of the memory device. As the degree of degradation increases while performing the fast SD operation on a page storing CSB data, the fast SD operation may be further applied to a page storing MSB data and a page storing LSB data. Also, as the number of cell regions to which the Fast SD is applied increases, the read performance of the memory device may gradually deteriorate. Subsequently, the reclaim operation may be performed on at least one block, and the flag value may be initialized. Since the read operation for the memory device is performed based on the normal read operation, the read performance of the memory device may increase again.

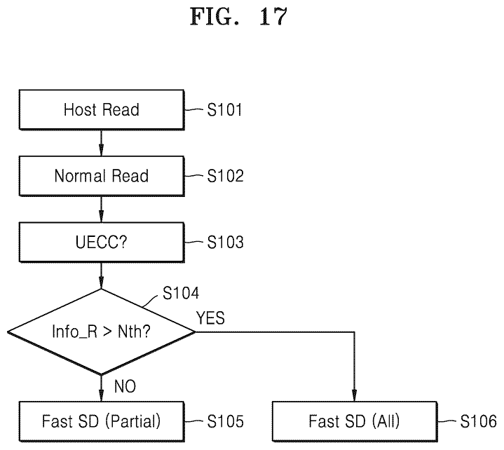

FIG. 17 is a flowchart showing a method of operating a memory controller, according to some embodiments. FIG. 17 shows an example operation when a normal read mode is set to a default mode.

Referring to FIG. 17, a memory controller may receive a read request from a host (S101) and perform a normal read operation to receive data (e.g., HD data), which is determined based on a normal read level, from a memory device in response to the read request (S102). The memory controller may determine whether a UECC exists in read data. When it is determined that the UECC exists (S103), the degree of degradation of the memory device may be determined based on reliability information Info_R according to the embodiments (S104).

It may be determined whether degradation information determined based on first reliability information exceeds a threshold Nth. Regarding the setting of fast SD mode for the memory device, when the degradation information does not exceed the threshold Nth, the memory controller may set a partial SD data read mode as the read mode of the memory device (S105). On the other hand, when the degradation information exceeds the threshold Nth, the memory controller may set the all-SD data read mode as the read mode of the memory device (S106).

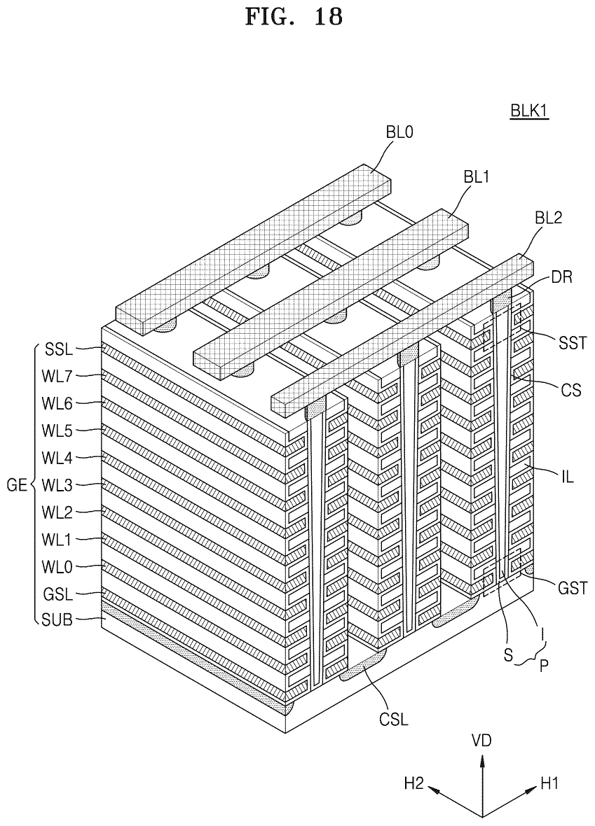

FIG. 18 is a perspective view showing a block BLK1 according to some embodiments. The block BLK1 of FIG. 18 may correspond to any one of the plurality of blocks of the memory device described in the above-described embodiments.

Referring to FIG. 18, the memory block BLK1 is formed, in a vertical direction VD, on a substrate SUB of first conductivity type (e.g., p type). In an embodiment, a common source line CSL doped with impurities of second conductivity type (e.g., n type) may be provided on (in) the substrate SUB. In an embodiment, the substrate SUB may include polysilicon, and the common source line CSL having a plate shape may be disposed on (in) the substrate SUB. A plurality of insulating films IL extending in a second direction H2 are sequentially provided above the substrate SUB in the vertical direction VD, and the plurality of insulating films IL are spaced apart from each other by a specific distance in the vertical direction VD. For example, the plurality of insulating films IL may include an insulating material, such as silicon oxide.

A plurality of pillars P may be sequentially arranged on the substrate SUB in a first direction H1 and may extend in (e.g., pass through) the plurality of insulating films IL in the vertical direction VD. For example, the plurality of pillars P may pass through the plurality of insulating films IL and come into contact with the substrate SUB. Specifically, a surface layer S of each of the pillars P may include a silicon material of first type and may function as a channel region. Accordingly, the pillar P may be referred to as a vertical channel structure. Also, an inner layer I of each of the pillars P may include an insulating material, such as silicon oxide, and/or an air gap.

A charge storage layer CS is provided along exposed surfaces of the insulating films IL, the pillars P, and the substrate SUB. The charge storage layer CS may include a gate insulating layer, a charge trap layer, and a blocking insulating layer. For example, the charge storage layer CS may have an oxide-nitride-oxide (ONO) structure. Also, a gate electrode GE, such as a ground selection line GSL, a string selection line SSL, and word lines WL0 to WL7, are provided on the exposed surface of the charge storage layer CS. Drains DR are respectively provided on the plurality of pillars P. For example, the drain DR may include a silicon material doped with impurities of second conductivity type. Bit lines BL1 to BL3 are provided on the drains DR, and the bit lines BL1 to BL3 extend in the first direction H1 and are spaced apart from each other by a specific distance in the second direction H2.

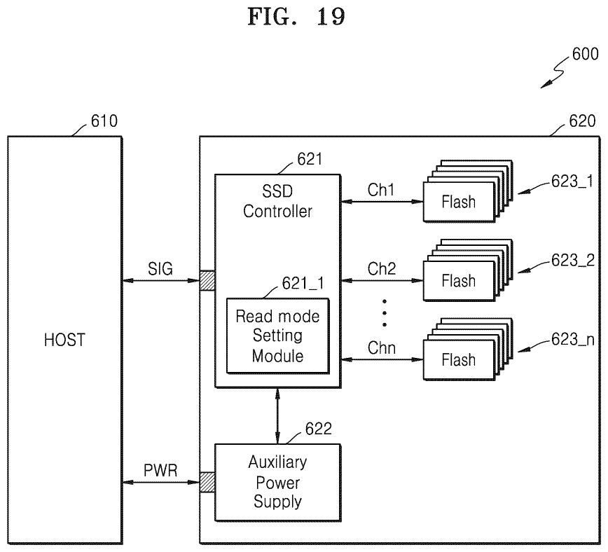

FIG. 19 is a block diagram showing an example in which a memory system according to some embodiments is applied to an SSD system.

Referring to FIG. 19, the SSD system 600 may include a host 610 and an SSD 620. The SSD 620 may exchange a signal SIG with the host 610 via a signal connector and receive power PWR via a power connector. The SSD 620 may include an SSD controller 621, an auxiliary power supply 622, and non-volatile memory devices 623_1 to 623_n. Herein, “n” is a natural number greater than 2. The non-volatile memory devices 623_1 to 623_n may include NOT-AND (NAND) flash memory or the like. Herein, the SSD 620 may be provided using the embodiments described above with reference to FIGS. 1 to 18.

Also, the SSD controller 621 may include the memory controller described in the above embodiment and include a read mode setting module 621_1 as in the above embodiment. The read mode setting module 621_1 may be provided based on hardware, software, or a combination thereof and may set a read mode for non-volatile memory devices 623_1 to 623_n. For example, depending on the degrees of degradation of the non-volatile memory devices 623_1 to 623_n, the data may be read from the non-volatile memory devices 623_1 to 623_n by applying the partial SD data read mode or the all-SD data read mode. In addition, the SSD controller 621 may store and manage the history RL information therein and may also store and manage the flag value representing a cell region, to which the fast SD is to be applied, among a plurality of cell regions of the non-volatile memory devices 623_1 to 623_n. Accordingly, when the degrees of degradation of the non-volatile memory devices 623_1 to 623_n are small, the read performance may increase on the basis of the normal read operation. Even when the degrees of degradation of the non-volatile memory devices 623_1 to 623_n increase, the degradation of read performance may be minimized by optimizing and managing the cell regions to which the fast SD is applied.

While the inventive concept has been particularly shown and described with reference to embodiments thereof, it will be understood that various changes in form and details may be made therein without departing from the scope of the following claims.

What is claimed is:

1. An operating method of a memory controller configured to control a memory device, the operating method comprising:
setting a read mode of the memory device to one of a normal read mode, a partial soft decision (SD) data read mode, and an all-SD data read mode, based on first reliability information and second reliability information representing a degree of degradation of the memory device;
selectively receiving hard decision (HD) data, which is read from a first cell region of the memory device, in response to outputting a first read command for the first cell region of the memory device in the partial SD data read mode; and
receiving HD data and SD data, which are read from a second cell region of the memory device, in response to outputting a second read command for the second cell region of the memory device in the partial SD data read mode.

2. The operating method of claim 1, wherein the first reliability information and the second reliability information represent first information, and
wherein the normal read mode is set when the degree of degradation of the memory device determined by the first information is less than a first threshold, the partial SD data read mode is set when the degree of degradation of the memory device determined by the first information is greater than the first threshold and less than a second threshold, and the all-SD data read mode is set when the degree of degradation of the memory device determined by the first information is greater than the second threshold.

3. The operating method of claim 2, wherein the first information corresponds to a number of program/erase cycles of the memory device.

4. The operating method of claim 2, wherein the first information corresponds to a number of errors or a bit error rate in data that is read from the memory device.

5. The operating method of claim 1, further comprising receiving HD data and SD data, which are read from the first cell region of the memory device, in response to outputting the first read command for the first cell region of the memory device when the all-SD data read mode is set.

6. The operating method of claim 1, wherein the memory controller is configured to control a read operation for a plurality of pages in the memory device,
wherein the plurality of pages comprises a first page storing most significant bit (MSB) data, a second page storing central significant bit (CSB) data, and a third page storing least significant bit (LSB) data, and
wherein the first cell region comprises at least one of the first page, the second page, or the third page, and the second cell region comprises at least another of the first page, the second page, and the third page.

7. The operating method of claim 1, wherein the memory controller is configured to control a read operation for a plurality of word lines in the memory device,
wherein each unit of the plurality of word lines is configured to store data of at least one page of the memory device, and
wherein the second cell region comprises at least one word line among the plurality of word lines.

8. The operating method of claim 1, wherein the memory controller is configured to control a read operation for a plurality of blocks in the memory device,
wherein each of the plurality of blocks comprises a plurality of word lines, and
wherein the second cell region comprises at least one block among the plurality of blocks.

9. The operating method of claim 2, wherein each of the first reliability information and the second reliability information comprises one selected from an information group of the memory device comprising a number of program/erase cycles, an offset value of history read level (RL) information, a number of errors or a bit error rate in read data, a number of iterations of error correction processing, and a number of decoding failures occurring in previously performed read operations.

10. The operating method of claim 9, wherein the memory controller comprises a storage circuit configured to store table information comprising the history RL information, and
wherein the storage circuit is configured to further store flag information representing the second cell region.

11. The operating method of claim 10, further comprising:
updating the offset value of the history RL information corresponding to a first block comprising the first cell region and second cell region when an uncorrectable error correcting code (UECC) occurs in data read from the first block; and
updating the flag information so that HD data and SD data are read from the first cell region when the degree of degradation of the memory device determined by the updated offset value exceeds the first threshold.

12. The operating method of claim 11, wherein SD data read from the first cell region or the second cell region is generated based on data sensed by at least two different sensing operations during a sensing period of a read operation in which a word line voltage having a normal read level is applied to a corresponding word line in the first cell region or the second cell region.

13. The operating method of claim 1, wherein, in the partial SD data read mode, the memory controller is configured to output a normal read command as the first read command for the first cell region and output an SD data read command as the second read command for the second cell region.

14. The operating method of claim 1,
wherein the memory controller is configured to output a partial SD data read command as the first read command for the first cell region and the second read command for the second cell region in the partial SD data read mode,
wherein the memory device is configured to transfer HD data to the memory controller in response to outputting the partial SD data read command for the first cell region, and
wherein the memory device is configured to transfer HD data and SD data to the memory controller in response to outputting the partial SD data read command for the second cell region.

15. A memory controller configured to control a memory device, the memory controller comprising:
a processor that is configured to control a read operation for the memory device; and
a read mode setting module that is configured to set a read mode of the memory device to a normal read mode when a degree of degradation of the memory device based on first reliability information is less than a first threshold and to set the read mode of the memory device to a partial soft decision (SD) data read mode when the degree of degradation of the memory device based on second reliability information is less than a second threshold,
wherein the memory controller is configured to selectively receive hard decision (HD) data, which is read from a first cell region of the memory device, in response to outputting a first read command for the first cell region of the memory device in the partial SD data read mode, and
wherein the memory controller is configured to receive HD data and SD data, which are read from a second cell region of the memory device, in response to outputting a second read command for the second cell region of the memory device in the partial SD data read mode.

16. The memory controller of claim 15, wherein the read mode setting module is configured to set the read mode of the memory device to an all-SD data read mode when the degree of degradation of the memory device based on the second reliability information exceeds the second threshold, and
wherein the memory controller is configured to receive HD data and SD data, which are read from the first cell region of the memory device, in response to outputting the first read command for the first cell region of the memory device in the all-SD data read mode.

17. The memory controller of claim 16, further comprising:
a storage circuit that is configured to store flag information representing a cell region of the memory device from which SD data is to be output,
wherein the read mode setting module is configured to update the flag information according to the degree of degradation of the memory device.

18. The memory controller of claim 15, wherein each of the first reliability information and the second reliability information corresponds to a number of program/erase cycles of the memory device, and
wherein the partial SD data read mode is set when the number of program/erase cycles is between the first threshold and the second threshold.

19. A memory device communicating with a memory controller, the memory device comprising:
a cell array that comprises a plurality of blocks, wherein each of the plurality of blocks comprises a plurality of word lines, and memory cells of each of the plurality of word lines are configured to store data of a plurality of pages; and
a control logic that is configured to set a read mode for the cell array to one of a normal read mode, a partial soft decision (SD) data read mode, and an all-SD data read mode, based on mode setting information provided from the memory controller,
wherein the memory device is configured to selectively output hard decision (HD) data, which is read from a first cell region of the cell array, in response to receiving a first read command for the first cell region of the cell array in the partial SD data read mode, and
wherein the memory device is configured to output HD data and SD data which are read from a second cell region of the cell array, in response to receiving a second read command for the second cell region of the cell array in the partial SD data read mode.

20. The memory device of claim 19, wherein the memory device is configured to receive the mode setting information that sets the all-SD data read mode as a degree of degradation of the cell array increases, and
wherein the memory device is configured to output HD data and SD data, which are read from the first cell region of the cell array, in response to receiving the first read command for the first cell region of the cell array in the all-SD data read mode.
